(19) United States
(12) Patent Application Publication
(10) Pub. No.: US 2002/0052129 A1
(43) Pub. Date: May 2, 2002

(54) Wafer probe assemblage with spring enhanced needles

(76) Inventor: Albert G. Cabintos, Itogon (PH)

Correspondence Address: Gary C. Honeycutt, Godwin Gruber,P.C., Suite 655, 801 E. Compbell Rd., Richardson, TX, 75081, US

(21) Appl. No.: 10/001,386

(22) Filed: Oct. 25, 2001

Related U.S. Application Data
(60) Provisional application No. 60/244,451, filed on Oct. 31, 2000.

(51) Int. Cl. H05K 1/00

(52) U.S. Cl. 439/70

(57) ABSTRACT

An improved probe card and needle assemblage for electrically contacting and testing integrated circuit wafers minimizes damage to metallization on chip pads, and reduces probe card maintenance and repair. The improved probe needle assemblage includes both a primary and secondary spring mechanism which allows the needle tip to adjust to differences in height between probes, thereby not only minimizing damage, but also simplifying probe card fabrication. The improved probe needle assemblage is compatible with probe cards and automated test equipment of known art.

### FIELD OF THE INVENTION

This invention relates to the testing of integrated circuits, and more particularly to an improved probe card and needle used in the testing of integrated circuits.

### DESCRIPTION OF PRIOR ART

Integrated circuits (ICs) are formed as multiple, identical, discrete chips on a semiconductor crystal wafer. Each of the integrated circuit chips is usually tested to determine whether or not it functions as intended prior to cutting the wafer into individual chips. Typically, the chips are tested by computer operated test apparatus that exercises the circuits on the chips, using a testing process commonly referred to as multiprobe testing.

Multiprobe testing typically employs a probe card which includes a plurality of electrical leads terminating in probe needles, which in turn make contact with input/output contacts of the various circuit elements on the integrated circuit chip being tested. The chip contacts most often are the pads to be electrically connected to the next level of circuitry, and are called bond pads.

In the prior art, it is typical for probe cards to be built by attaching metal needles, such as tungsten to conductive traces on a polymeric substrate. The needles, or probe elements may be secured to the substrate by an adhesive or they may be bonded, as by welding to a blade. On some probe cards as shown in FIG. 1, the probe needle 11 connection to the card 10 includes a mechanical spring 15 which allows some flexibility in the probe positioning on the wafer 12.

The probe card includes an opening in the center through which the tips of the needles extend for viewing alignment of the needles to the bond pads. The card is positioned in a probe head which provides electrical connection to the controlling computer, and which mechanically brings the needles into contact with the bond pads on the chip. After the probe needle has been brought into contact with the bond pads, a prescribed pressure is applied between the probe needles and pad. The pressure allows the needle tips to move on the pad surface removing oxides and contamination on the pads, and thus providing a suitable surface for electrical contact.

The needle tips must all fall in the same place in order to assure that each one makes electrical contact with a bond pad on the integrated circuit. The relation in position of the probe needle and the pad must be carefully considered in directions of length, width, and height, each requiring accuracy of about plus or minus 10 microns. Presently, this is accomplished by bending the needles after they are mounted on the probe card, which is laborious, time consuming, and in turn insures a high cost. Moreover, the adjustment of the height of the probe needles is extremely difficult both initially and after use. Further, delivery of such cards adds significantly to the cycle time of testing.

Failure of the probes to be perfectly aligned in the vertical direction allows the opportunity for damage to the soft metal of the bonding pads, particularly by those probes which come into contact first and are driven into the metal before the remaining probes make contact. Damaged bonding pads are extremely difficult to wire bond, or to cover with a thin film metallization, in the case of flip chip devices. Such bond pad metallization failures result in costly final assembly yield degradation of the integrated circuit devices.

It is extremely difficult to fabricate a probe card with completely planar needles so that they all make contact at the same time, and even more difficult to assure that the probe needle tips remain in the same plane after they are put into use. Contacting and scrubbing motions against the chip pads tend to move the probe tips out of position and to damage fine tips. This in turn results not only in excessive abrasion of some pads, but requires time consuming and costly maintenance of the probe cards.

These issues have become more significant as the geometry on integrated circuits have become smaller. The metallization is thinner and more fragile, but yet both aluminum and copper pads are subject to oxidation which must be removed in order to make good electrical contact.

Because of the aforementioned issues with prior probe card technologies, and because of the anticipation of even tighter pitch of bond pads on integrated circuits of the future requiring finer pitch probe needles, and of thinner and more readily damaged bond pad metallization, it would be very advantageous for the industry to have an improved probe card needle which minimizes damage to bond pad, as well as one that is relatively low cost apparatus with respect to fabrication, and maintenance.

### SUMMARY OF THE INVENTION

It is an object of the current invention to provide a new and useful probe card which enables connection between input/output pads on an integrated circuit chip and an electrical test equipment.

It is also an object of the invention to provide a probe card having a needle assemblage which minimizes damage to bond pads on the chip, as compared to those devices of known art.

It is yet another object of the invention to provide a robust probe needle assemblage which minimizes the amount of probe card maintenance required during and after usage.

It is further an object of this invention to provide a probe needle assemblage capable of self adjusting to thermal expansion of the semiconductor device under test so that contact is not compromised as a result of chip heating during testing.

It is an object of the invention to provide a probe needle assemblage which is compatible with existing probe card technology, and tester operation.

Yet another object of the current invention is to provide an economical and reliable probe card and needle assemblage.

It is also an object of the invention to provide an improved probe needle assemblage for various electrical contact applications.

The objectives of this invention are met by providing a wafer probe card and needle assemblage having a primary spring connection between conductors on the card and the first end of each primary needle segment, and an additional spring connection between the primary segment and a probe needle tip segment which allows the tip to move and self adjust in the vertical direction. The secondary spring allows an out of plane probe needle tip to make minor position adjustments, and thus avoid damage to the bond pad metallization whilst the remaining probes are being brought into contact.

As the needles are brought into contact with the chip, force on the somewhat fragile needle tips is reduced by addition of a secondary spring, thus minimizing damage to the needle tips. Further, the compliant spring largely eliminates damage to probe needle tips during use resulting from either the needles becoming misaligned, or the tips deformed, and therefore, probe card maintenance is significantly reduced.

The addition of a secondary spring to probe needles is compatible with existing procedures in that the new probes require no changes to the overall probe card, or to the probing process. Further, the added compliance of secondary springs minimizes damage to probe needles during use and avoids time consuming and costly probe card maintenance.

The probe cards having needles with primary and secondary springs are formed by a providing a primary probe segment attached by a primary mechanical spring to a conductor on a card, and the segment having a groove formed near the opposite end. The secondary spring connects the primary segment within the base of the groove to a needle tip segment. The tip is guided through the opening in the groove by metallic pivots or bearings attached to the inner wall of the groove and to opposite sides of the probe needle segment. The needle tip extends beyond the protruding walls of the groove and is able to move vertically on the pivots, and thus compensate for differences in height between various needles on the probe card. This movement minimizes force placed on the chip pads by out of plane needles and reduces damage to both the pads and needles. Electrical connection is made between the needle tip and probe segments primarily through the metallic pivots and secondarily through the spring.

The foregoing and other objectives, features and advantages will become more apparent from the following detailed description of preferred embodiments of the invention which proceeds with reference to the accompanying drawings.

### BRIEF DESCRIPTION OF THE DRAWINGS

FIG. 1 schematically depicts a single spring loaded wafer probe assembly of existing technology.

FIG. 2 illustrates a probe card of the current invention having a plurality of enhanced secondary spring needle assemblages.

FIG. 3 is a top view of a enhanced secondary spring needle assemblage of the current invention.

FIG. 4 illustrates the primary and secondary flow of current through the probe needle assembly of the current invention.

### DETAILED DESCRIPTION OF THE INVENTION

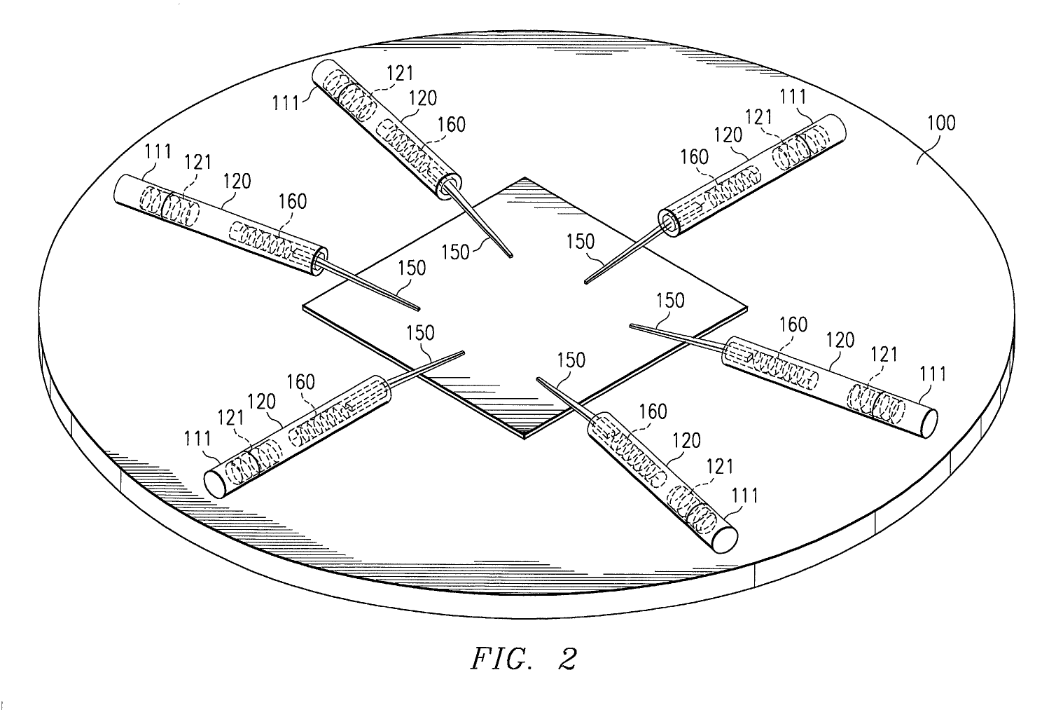

In FIG. 2 a probe card of the current invention includes a plurality of primary probe segments 120 precisely arrayed and secured in position on a supporting probe card 100. A primary mechanical spring 121 connects each primary probe segment 120 to a conductor 111 on the dielectric card substrate 100, and a secondary spring 160 connects the opposite end of the probe segment 120 to a fine tipped needle segment 150.

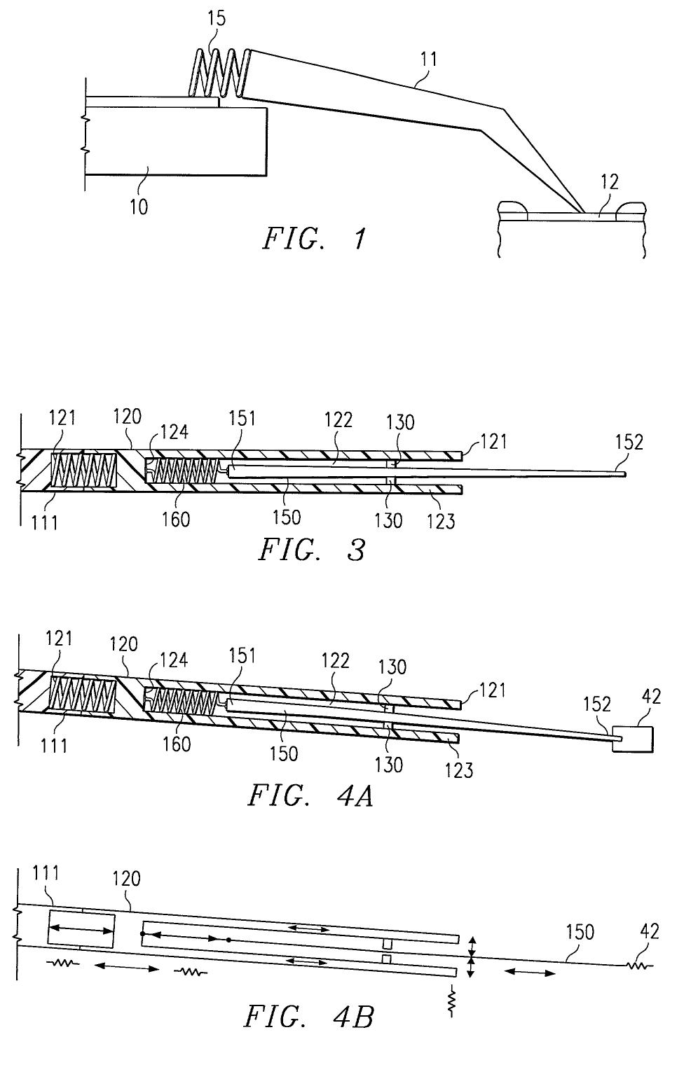

By way of contrast to a single spring loaded probe needle assemblage of known art, and depicted in FIG. 1, the enhanced probe needle apparatus of the current invention in FIG. 3 includes a probe needle segment 150 having a broader end 151 and a fine tip 152. The broader end 151 is attached to the primary probe segment 120 both by a secondary spring 160, and near midway along the length of the needle by a pair of pivots 130. This configuration allows the needle tip to move vertically, and thus to conform to height differences between multiple needle tips on the probe card, and to make contact with a bond pad without being forced as by the more rigid single spring loaded probe needles 11 in FIG. 1.

The detailed drawing in FIG. 3 of the spring enhance needle assemblage shows the needle tip 150 with spring 160 attached to a primary probe segment 120 having a primary spring 121. It can be seen that the primary probe segment 120 terminates in a blunt end 121, and that the center has been stamped or otherwise formed to make a groove 122 or lengthwise channel, and two parallel protrusions 123 on either side of the groove.

A coiled spring 160 of variable length formed from a conductive material connects the broader end 151 of the fine tipped needle 150 to the base 124 of the groove in the probe segment 120.

It can further be seen in FIG. 3 that the needle segment 150 is held at a fixed space from each of the parallel protrusions 123 by a pair of pivotal pins 130. The pivots 130 formed from a conductive material, such as a copper alloy, serve both as a guide for the tips to move vertically, and thus be able to compensate for difference in the needle tip heights tip with respect to bond pads, and as an electrical conduction path between the needle tip and primary probe segment. The pivots, formed as rods or pins, or as spherical elements connect the inner sides of the protrusions on the primary segment to opposite sides of the needle segment. The pivots are located on the protrusions, equidistant from the ends of the protrusions, directly opposite each other, and are about one forth to one half the length of the pin 150 from the spring contact 160.

It is very important that the resistivity of a probe needle arrangement be both very low, and be consistent between needles in order to provide accurate electrical test results. Arrows in FIG. 4 diagram the primary conduction path of the enhanced probe needles of the current invention from the chip pads 42 to conductors 111 on the probe card. The minimum distance and thus the primary conduction path between the needle tip 152 which in turn contacts test pads 42 on a wafer, and conductors to an electrical test unit are through the needle segment 150 to conductive pivot pins 130, and to the broader primary probe segment 120. The secondary spring 160 provides an alternate path, but length and diameter of the thin coil are less optimized than the short and direct path through the relatively broad pivots 130.

Very fine tip probe needles have become highly desirable in order to make contact with closely spaced bond pads of integrated circuits, but fragile tips are subject to damage both from blunting the tips themselves due to repeated contact, and from misalignment resulting from overdriving the needles to compensate for non-uniformity in height between needles. Both types of failures result in costly maintenance of the probe card, and loss of productivity for shut down of the test equipment. The robust secondary spring probe needle assemblage of the current invention provides a major advantage in lessening the amount of maintenance needed. The self aligning feature of the secondary spring needle tip not only avoids damage, but also allows thinner, smaller diameter tips to be used for probe cards.

Probe segments of the current invention are fabricated of materials typically used within the industry, such as copper/beryllium, tungsten, or copper/tungsten alloys. Needles have a fine tip in the range of 0.00075 to 0.003 inches in diameter, and because of the small area, the tips may be economically coated with an oxidation and abrasion resistant coating, such as palladium or gold. The tips extend beyond the blunt end 121 of the probe segment 120 by at least 0.050 inches.

Integrated circuits typically heat in localized areas during electrical testing, and as a result of thermal expansion changes in the device under test, good ohmic contact of the probe needles is often compromised. With the secondary spring enhanced probe, the needles are able to move as the expansion changes, and to maintain good electrical contact.

Despite the significant differences between the secondary spring needle probes of the current invention in FIG. 3 and the existing single spring loaded probes shown in FIG. 1, it is important to note that no change is required in test equipment, and that the enhanced spring probe needles are assembled on the same types of probe cards, thus avoiding any costly changes upstream of the probes themselves.

A probe card of the current invention including a plurality of enhanced spring probe needle assemblages provides a reliable and useful improvement over probe cards of known technology. The secondary spring probe needle assemblage provides a number of innovative advantages to the semiconductor industry. The method of manufacture lends itself to relatively low cost and rapid cycle time, necessary to respond to the fast paced introduction of chip designs for both new and revised products. Manufacture of probe cards of the current invention is simplified with respect to existing technology by the following changes; the primary probe segments require a formed groove, rather than a fine tip. Needle tip segments are attached by a spring, and are held in position by pivots. These spring loaded needle tips significantly reduce the amount of time and effort required for alignment in the critical, vertical direction.

Enhanced spring probe needle tips extending below the card assemblage are brought into contact with chip pads by positioning and lowering the card and contact apparatus. Alignment may be partially or totally viewed through the centrally located opening in the card substrate. These features require little to no operator retraining from existing probe card technology.

The enhanced spring probe needle of the current invention has been described in connection with probe cards for testing of integrated circuit chips, but the usefulness of such a structure is not limited to this application, but instead may be applied as a low cost, robust and reliable contact mechanism for multiple applications. One such application, also related to the integrated circuit testing field is a burn-in contact mechanism, wherein the enhanced spring loaded probe tips are held in contact with a packaged semiconductor device for aging under electrical and thermal stress.

The invention has been described with reference to specific embodiments, but it is not intended to limit the scope to a particular form set forth, but on the contrary, it is intended to cover alternatives, modifications, and equivalents as may be included within the spirit of the invention as described by the appended claims.

What is claimed is:

1. A probe card having a plurality of probe needle assemblages of which the tips are brought into contact with pads on an integrated circuit for transmitting an electrical signal from the IC to a tester, comprising in combination:
a plurality of primary probe segments connected by mechanical springs to conductors on a dielectric probe card substrate,
each of said primary segments including a groove and two parallel protrusions formed in the end of the segment opposite the card connection,
a fine tipped probe needle segment situated within opening in said groove and attached by a secondary mechanical spring to the primary probe segment between the parallel protrusions,
a pair of pivots connecting each of said parallel protrusions of the probe segment to the needle segment,
and the tip of each needle segment extending beyond the parallel protrusions.

2. A probe card as in claim 1 wherein said probe needle tips adjust vertically to compensate for height differences between probes on said card.

3. A probe card as in claim 1 wherein said probe needle tips adjust vertically to compensate for thermal expansion changes.

4. A probe card as in claim 1 wherein electrical conduction between said needle tips and primary probe segment is via the pivots.

5. A probe needles assemblage as in claim 1 wherein said probe segments comprise tungsten.

6. A probe needle assemblage as in claim 1 wherein said probe segments comprise a copper/tungsten alloy.

7. A probe needle assemblage as in claim 1 wherein said probe segments comprise a copper/beryllium alloy.

8. An assemblage as in claim 1 wherein said probe needle tips are covered with an abrasion or oxidation resistant coating.

9. An assemblage as in claim 1 wherein said needle tips extending beyond the parallel protrusions by at least 0.050 inches.

10. An assemblage as in claim 1 wherein said needle tips are in the range of 0.00075 to 0.003 inches thick.

11. An assemblage as in claim 1 wherein said pivots comprise a conductive metal.

12. An assemblage as in claim 1 wherein said pivots are rod shaped.

13. An assemblage as in claim 1 wherein said pivots are spherical.

14. An assemblage as in claim 1 wherein said pivots comprise a copper alloy.

15. An assemblage as in claim 1 wherein said secondary spring is a variable length coil.

16. An assemblage as in claim 1 wherein said secondary spring is electrically conductive.

17. A probe needle assemblage including in combination;
a primary segment having a groove with two parallel protrusions formed in one end and a mechanical spring attachment on the opposite end,
a fine tipped probe needle segment connected by a secondary mechanical spring to said primary probe segment between the parallel protrusions,
a pair of pivots connecting each of said parallel sides of the probe segment to the needle segment, and
the needle tip extending beyond the parallel protrusions.

18. A method of manufacturing a probe card having spring enhanced probe needle assemblages of which the tips are brought into contact~with pads on an integrated circuit for transmitting an electrical signal from the IC to a tester, including the following steps:
providing a probe card substrate having a pattern of conductors on the surface,
providing a plurality of primary probe segments having a groove and two parallel protrusions formed in one end, and connecting the second end by a mechanical spring to a conductor on the card,
providing a conductive pivot member connected to each of the protrusions, spaced equidistant from the ends of the protrusions, and extending into the cavity space of the groove,
providing a plurality of fine tipped needles greater in length than the protrusions,
attaching the broader end of said needle tips to a secondary spring, and in turn, that spring to the primary probe segment, and
connecting the pivots to the needle segment about one quarter to one half of the distance from the broader end of the needle segment.
